(19) United States
(12) Patent Application Publication
(10) Pub. No.: US 2018/0366902 A1
(43) Pub. Date: Dec. 20, 2018

(54) LASER PROJECTOR WITH ANGLED REFLECTOR

(71) Applicant: Intel Corporation, Santa Clara, CA (US)

(72) Inventors: Wei Shi, Gilbert, AZ (US); Xianyang Cai, Santa Clara, CA (US)

(21) Appl. No.: 15/782,013

(22) PCT Filed: Dec. 23, 2015
(86) PCT No.: PCT/US2015/000256

§ 371 Date: Jun. 6, 2018

(51) Int. Cl. H01S 5/022; G02B 27/09; G02B 5/02; G03B 21/20

(52) U.S. Cl. CPC H01S 5/02292; G02B 27/0955; G02B 5/0215; H01S 5/02276; G03B 21/2033; H01S 5/02208; G02B 5/0278

(57) ABSTRACT

A laser projector includes a substrate having an angled reflective surface. A laser is supported by the substrate and positioned to direct laser light onto the angled reflective surface. A patterned diffuser is supported relative to the angled reflective surface to receive reflected laser light and provide a projected pattern of light away from the substrate.

### TECHNICAL FIELD

Embodiments described herein generally relate to laser projectors, and more particularly to small form factor laser projectors.

### BACKGROUND

Infrared (IR) laser projectors are used to project a dot pattern image which may be used by IR cameras to calculate a z-depth of an object. Some current IR laser projectors are made using a convention plastic molding process that uses a plastic-molded lens cover which further increases an IR laser projector package size.

### BRIEF DESCRIPTION OF THE DRAWINGS

FIG. 1 is block cross section view of a projector according to an example embodiment.

FIG. 2 is a top view of the projector of FIG. 1 according to an example embodiment.

FIG. 3 is a block cross section diagram illustrating an alternative projector according to an example embodiment.

FIG. 4 shows cross section representations illustrating formation of a diffuser according to an example embodiment.

FIG. 5 is a top view of one embodiment of a diffuser mold according to an example embodiment.

FIG. 6 is a block diagram of a 3D sensor assembly utilizing a projector according to an example embodiment.

FIG. 7 is a block cross section diagram of a further alternative projector according to an example embodiment.

FIG. 8 is a flowchart illustrating a method of using one of the projectors according to an example embodiment.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

In one or more embodiments of the inventive subject matter, a groove in a substrate provides a structure for forming a reflective surface, a laser to project light toward the reflective surface, and a diffuser supported to receive and project a pattern from the light reflected by the reflective surface. The use of a groove to create the angled reflective surface, diffuser, and positioning of the laser may provide one or more benefits over prior projectors utilized in 3D sensors, including a reduced size or form factor, repeatable and accurate process for molding the diffuser, accurate laser spot size, control, and laser pattern uniformity by fixing the position of the laser with respect to the reflector and diffuser, and a better pattern stability.

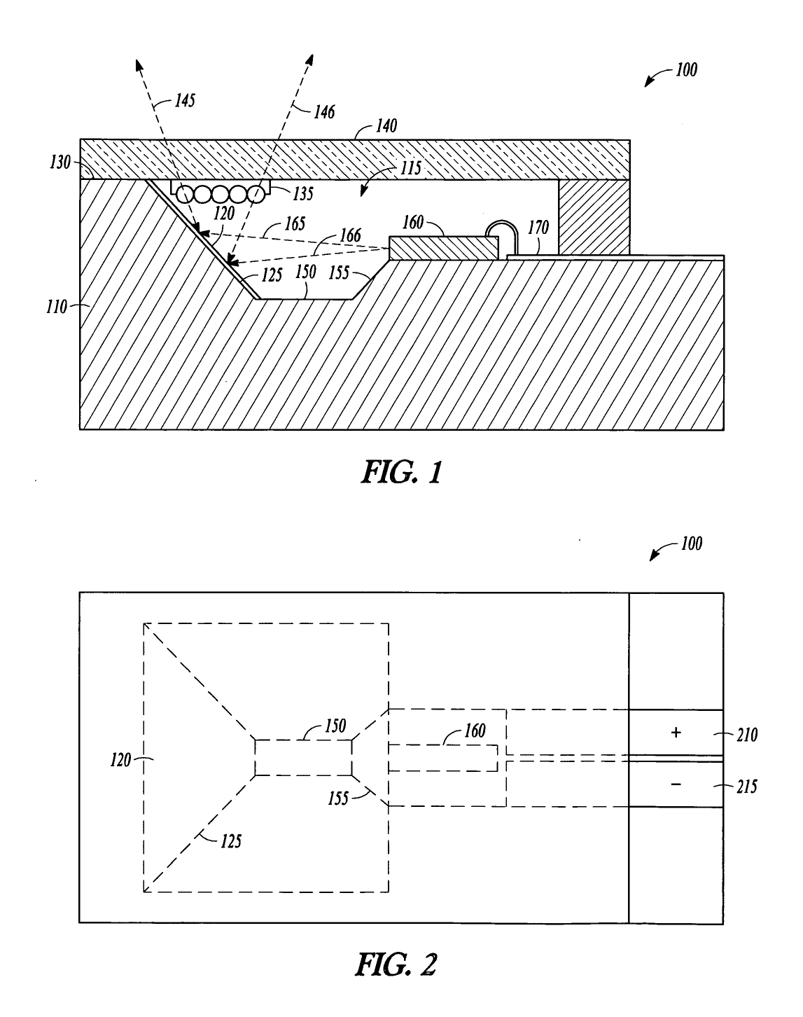

FIG. 1 is a block cross section view of a projector 100. The projector 100 may be a laser projector that is formed on a substrate 110, which may be semiconductor substrate such as a silicon substrate or other material in which the structures described may be formed.

The substrate 110 in one embodiment may have groove 115 formed in it, such as by v-etching. Etched surfaces of the groove 115 may have detectable physical features consistent with the formation of the groove by etching. The groove 115 has a first angled surface 120 with a reflective layer 125 formed on it to create a reflective angled surface 120. The angled surface may form a 45° angle from a top surface 130 of the substrate 110 in one embodiment.

A diffuser 135 may be formed above the angled surface and in one embodiment may be supported by a glass plate 140. The diffuser 135 may be a patterned polymer molded on the glass plate 140 and positioned to receive light reflected from the angled reflective surface 120 as represented by lines 145 and 146. The light 145, 146 from the angled reflective surface 120 is diffused by diffuser 135 and forms a pattern of light that is projected away from the substrate 110 as also represented by lines 145 and 146.

The groove 115 in one embodiment may have a floor 150 in a bottom of the groove 115 and a second angled surface 155 extending up from the floor a distance to facilitate supporting a laser 160 that projects light toward the angled reflective surface indicated by lines 165 and 166, which is the light that is reflected as indicated by lines 145 and 146. The laser 160 may be supported on a flat surface 170 of the substrate that is lower than the top surface 130, and may be formed by grinding or other process to form a surface suitable for mounting the laser and forming metalized layer including wirebond pads or connections 210, 215 as indicated in a top view in FIG. 2 of the projector 100. The laser 160 may be soldered onto a metalized layer. A spacer 175 may be positioned between the flat surface 170 and the glass plate 140 to facilitate formation of a hermetic seal of the groove 115 that contains the reflective surface 125, diffuser 135, and laser 160. Spacer 175 may comprise AlN in one embodiment, or other compatible material that may be formed on the substrate.

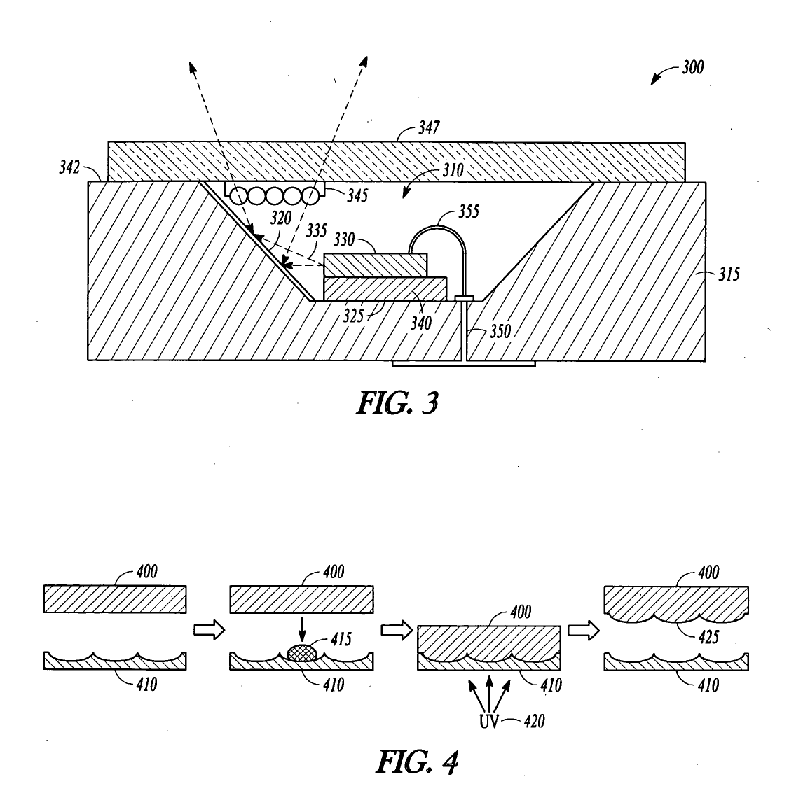

FIG. 3 is a block cross section diagram illustrating an alternative projector 300. Projector 300 also has an etched groove 310 formed in substrate 315. One side of the groove 310 forms a reflective surface 320, while a bottom 325 of the grove 310 supports a laser 330 that projects laser light 335 toward the reflective surface 320. A spacer 340, which may be formed of AlN or other material, may be positioned between the bottom 325 of the groove 310 and the laser 330 to support the laser a desired height above the bottom surface 320 such that the laser light 335 impinges on the reflective surface 320 at a desired height, and substantially parallel to a top surface 342 of the substrate 315. The top surface 342 of the substrate 315 in one embodiment supports a diffuser 345 which is positioned to receive the laser light 335 reflected from the reflective surface 320 and project it away from the substrate 315. In one embodiment, the diffuser 345 is supported by a glass plate 347 that may span the groove 310 and form a seal with the top surface 342 of the substrate 315. The glass plate may form a hermetic seal with the substrate 315 in one embodiment. Conductive metal filled vias 350 may be formed in the substrate in the bottom 325 of the groove 310 and used to form contacts 355 with the laser 330. The vias 350 may be formed of cupper in some embodiments, and wire bonded to the laser.

The laser 330 in one embodiment is positioned horizontally distanced from, and projects light 335 in a generally horizontal direction toward, the angled reflective surface 320. The angled reflective surface 320 may comprise an etched silicon groove in the substrate 315. The reflective surface 320 may be metalized with one or more of gold or silver, or coated with other reflective metal or material.

The use of groove to create the angled reflective surface, diffuser, and positioning of the laser may provide one or more benefits over prior projectors, including a reduced size or form factor, repeatable and accurate process for molding the diffuser, accurate laser spot size, control, and laser pattern uniformity by fixing the position of the laser with respect to the reflector and diffuser, and a better pattern stability.

A method of forming a patterned diffuser used in one or more embodiments is illustrated in block cross section form in FIG. 4. FIG. 4 is a cross section of a substrate 400 on which the diffuser will be formed. The substrate may be glass in one embodiment. A mold is illustrated at 410, having a pattern of concave structures indicated at 412 approximately 50 μm in diameter with approximately 100 μm center to center pitch in one embodiment. Different pitches and structure diameters may be used in different embodiments to provide a desired projected pattern. The pitch identified in the described embodiment provides a projected pattern that is sufficient to about a ten meter distance from the substrate or device incorporating the projector.

At least one pellet or lump of polymer placed in one concave structure at 415. The polymer may be placed in all or multiple structures and the mold is aligned with the substrate 400. The aligned mold 410 pressed to the substrate 400 such that the polymer is spread out and molded to the substrate 400. Curing of the polymer may be performed by applying suitable ultraviolet (UV) light as indicated at 420.

The mold 410 maybe removed from the substrate 400 following curing, leaving a diffuser 425 consisting of convex structures formed to diffuse light and produce a desired pattern. The diffuser comprises a means to receive laser light reflected from the angled reflective surface and provide a projected pattern of light away from the substrate. The use of the mold to form the structures on glass may be referred to as glass replication technology and provides a very uniform pattern which results in a uniform laser light pattern, which may improve 3D sensor reliability. The diffuser may be formed using other processes in further embodiments, such as laser cutting of a polymer sheet bonded to a transparent substrate, or other known processes.

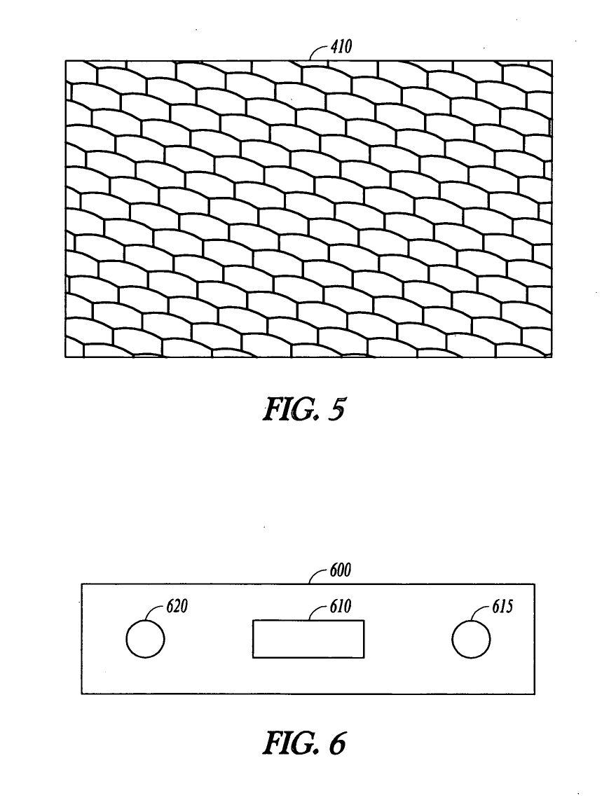

FIG. 5 is a top view of one embodiment of the mold 410. The mold 410 contains offset rows of concave oval like structures in one embodiment having the above described center to center pitch. Other shaped structures may be formed in further embodiments to produce other patterns of light that are suitable for determining z-depths of objects illuminated by the patterns within a selected distance. The distance is selected having a range suitable for observing deformations of the projected pattern and calculating z-depths of the object from such projected pattern.

FIG. 6 is a block diagram of a 3D sensor assembly 600 that utilizes one of the various projector embodiments indicated at 610 in conjunction with one or more cameras indicated at 615 and 620. The projector 610 may be supported in the assembly 600 between the two cameras 615 and 620. In one embodiment, the projector laser comprises an infrared (IR) laser. The projector 610 may be used to project a dot pattern image which may be used by the IR cameras 615 and 620 to calculate a z-depth of an object. They spacing between the projector and cameras may be varied to meet requirements of different applications, but may be the same as the spacing of prior projectors and cameras in some embodiments.

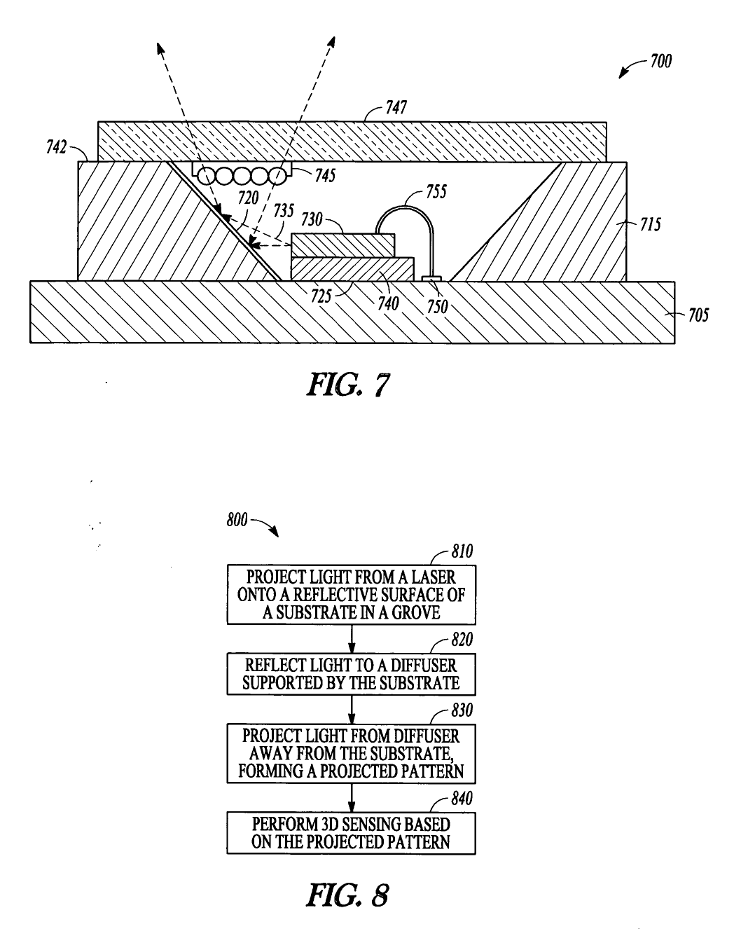

FIG. 7 is a block cross section diagram of a further alternative projector 700 according to an example embodiment. Projector 700 is supported by and may be formed on a printed circuit board (PCB) 705 in one embodiment. An etched groove 710 is formed in a substrate 715 which may be grown on and is supported by the PCB 705. Similarly to projector 300, one side of the groove 710 forms a reflective surface 720, while a bottom 725 of the grove 710 supports a laser 730 that projects laser light 735 toward the reflective surface 720. A spacer 740, which may be formed of AlN or other material, may be positioned between the bottom 725 of the groove 710 and the laser 730 to support the laser a desired height above the bottom surface 720 such that the laser light 735 impinges on the reflective surface 720 at a desired height, and substantially parallel to a top surface 742 of the substrate 715. The top surface 742 of the substrate 715 in one embodiment supports a diffuser 745 which is positioned to receive the laser light 735 reflected from the reflective surface 720 and project it away from the substrate 715. In one embodiment, the diffuser 745 is supported by a glass plate 747 that may span the groove 710 and form a seal with the top surface 740 of the substrate 715. The glass plate may form a hermetic seal with the substrate 715 in one embodiment.

In one embodiment the groove 710 is etched to the PCB 705 at a top layer of the PCB where circuitry may be formed as indicated at 750. Wires 755 may be bonded to the circuitry 750 comprising bonding pads to provide power to the laser 730.

The laser 730 in one embodiment is positioned horizontally distanced from, and projects light 735 in a generally horizontal direction toward, the angled reflective surface 720. The angled reflective surface 720 may comprise an etched silicon groove in the substrate 715. The reflective surface 720 may be metalized with one or more of gold or silver, or coated with other reflective metal or material.

The use of groove to create the angled reflective surface, diffuser, and positioning of the laser may provide one or more benefits over prior projectors, including a reduced size or form factor, repeatable and accurate process for molding the diffuser, accurate laser spot size, control, and laser pattern uniformity by fixing the position of the laser with respect to the reflector and diffuser, and a better pattern stability.

FIG. 8 is a flowchart illustrating a method 800 of using one of the projector embodiments described above. At 810, light from a laser is projected onto a reflective surface of a substrate. The laser is supported by the substrate opposite the reflective surface in a groove formed in the substrate. At 820, the laser light is reflected via the reflective surface to a diffuser supported by a surface of the substrate. Method 800 includes projecting light received at the diffuser away from the substrate as indicated at 830. The projected light forms a pattern suitable for 3D sensing at 840 by one or more cameras.

To better illustrate the projector, a non-limiting list of examples is provided herein:

Example 1 includes a laser projector including a substrate having an angled reflective surface. A laser is supported by the substrate and positioned to direct laser light onto the angled reflective surface. A patterned diffuser is supported relative to the angled reflective surface to receive reflected laser light and provide a projected pattern of light away from the substrate.

Example 2 includes the laser projector of example 1 and further including a glass layer coupled to the substrate and wherein the patterned diffuser is coupled to the glass layer.

Example 3 includes the laser projector of example 2 wherein the patterned diffuser comprises a polymer molded onto the glass layer.

Example includes the laser projector of example 2 and further comprises a spacer coupled between the glass layer and the substrate forming a hermetic seal about the laser, angled reflective surface, and patterned diffuser.

Example 5 includes the laser projector of any of examples 1-4 wherein the laser is supported by a metalized layer of the substrate.

Example 6 includes the laser projector of example 5 wherein the laser is positioned to project light in a direction parallel to a substrate surface and toward, the angled reflective surface.

Example 7 includes the laser projector of any of examples 1-4 wherein the angled reflective surface comprises an etched silicon groove in the substrate and a metalized reflective layer supported on the etched silicon groove.

Example 8 includes the laser projector of example 7 wherein the metalized reflective layer comprises gold or silver.

Example 9 includes the laser projector of any of examples 1-4 wherein the patterned diffuser comprises a pattern of concave polymer structures having an approximately 100 μm center to center pitch.

Example 10 includes the laser projector of example 9 and further comprises a glass layer coupled to the substrate and wherein the patterned diffuser is molded on the glass layer.

Example 11 includes a laser projector including a substrate having a groove with an angled reflective surface. A laser is supported by the substrate and positioned to direct laser light onto the angled reflective surface of the groove. A diffuser is supported above at least a portion of the angled reflective surface of the groove and positioned to receive reflected laser light and provide a projected pattern of light away from the substrate.

Example 12 includes the laser projector of example 11 wherein the diffuser is positioned substantially parallel to a top surface of the substrate such that the projected pattern of light is projected orthogonal to the top surface of the substrate.

Example 13 includes the laser projector of any of examples 11-12 wherein the groove has a shorter angled surface opposite the angled reflective surface, the shorter angled surface rising from a bottom of the groove to a flat laser support surface of the substrate, the laser support surface rising to a height part way up the angled reflective surface, below a top of the substrate at top of the angled reflective surface.

Example 14 includes the laser projector of example 13 and further includes a glass layer supported by the top of the substrate. The diffuser is supported by the glass layer. A spacer is positioned between the glass layer and the flat laser support surface of the substrate.

Example 15 includes the laser projector of example 14 and further comprises metal contacts supported by the flat laser support surface of the substrate and coupled to the laser to provide power to the laser.

Example 16 includes a laser projector including a substrate having an angled reflective surface. A laser is supported by the substrate and positioned to direct laser light onto the angled reflective surface. The projector also includes a means to receive laser light reflected from the angled reflective surface and provide a projected pattern of light away from the substrate.

Example 17 includes the laser projection of example 16 wherein the substrate comprises a silicon substrate and wherein the angled reflective surface comprises a side of a v-groove formed at 45 degree angle from a top surface of the silicon substrate.

Example 18 includes a method of forming a laser projector. The method includes creating an angled surface in a substrate, applying a reflective material to the angled surface, molding a diffuser to a plate of glass, and bonding the plate of glass with molded diffuser to the substrate.

Example 19 includes the method of example 18 wherein the molded diffuser is positioned above the angled surface of the substrate and further comprising attaching a laser to the substrate.

Example 20 includes the method of example 19 wherein the laser is attached to the substrate such that the laser projects a laser onto the reflective material applied to the angled surface.

Example 21 includes the method of example 19 and further comprises forming a metalized layer on the substrate to couple to the laser.

Example 22 includes the method of any of examples 18-21 wherein creating an angled surface in a substrate comprises performing silicon-V etching to create an approximately 45° groove.

Example 23 includes the method of example 22 and further includes forming a planar substrate surface lower than a top of the angled surface having the reflective material, and attaching a laser to the lower planar substrate surface such that laser light projected from the laser impinges on the reflective surface and is reflected though the diffuser.

Example 24 includes a method of projection light that includes projecting light from a laser onto a reflective surface of a substrate, wherein the laser is supported by the substrate, reflecting the light via the reflective surface to a diffuser supported by a surface of the substrate, and projecting light from the diffuser away from the substrate.

Example 25 includes the method of example 24 wherein the diffuser projects the light in the form of a pattern.

Example 26 includes the method of example 24 wherein the reflective surface comprises gold or silver.

Example 27 includes the method of any of examples 24-26 wherein the substrate comprises a silicon substrate.

Example 28 includes a laser projector including a means to reflect light. A laser is supported by a substrate and positioned to direct laser light onto the means to reflect light. A patterned diffuser is supported to receive reflected laser light and provide a projected pattern of light away from the substrate.

Example 29 includes the laser projector of example 28 and further comprising a glass layer coupled to the substrate and wherein the patterned diffuser is coupled to the glass layer.

Example 30 includes the laser projector of example 29 wherein the patterned diffuser comprises a polymer molded onto the glass layer.

Example 31 includes the laser projector of example 29 and further comprising a spacer coupled between the glass layer and the substrate forming a hermetic seal about the laser, means to reflect light, and patterned diffuser.

Example 32 includes the laser projector of any of examples 28-31 wherein the laser is supported by a metalized layer of the substrate.

This overview is intended to provide non-limiting examples of the present subject matter. It is not intended to provide an exclusive or exhaustive explanation. The detailed description is included to provide further information about the methods.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description.

The Abstract is provided to allow the reader to quickly ascertain the nature of the technical disclosure. It is submitted with the understanding that it will not be used to interpret or limit the scope or meaning of the claims.

Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1.-25. (canceled)

26. A laser projector comprising:
a substrate having an angled reflective surface;
a laser supported by the substrate and positioned to direct laser light onto the angled reflective surface; and
a patterned diffuser supported relative to the angled reflective surface to receive reflected laser light and provide a projected pattern of light away from the substrate.

27. The laser projector of claim 26 and further comprising a glass layer coupled to the substrate and wherein the patterned diffuser is coupled to the glass layer.

28. The laser projector of claim 27 wherein the patterned diffuser comprises a polymer molded onto the glass layer.

29. The laser projector of claim 27 and further comprising a spacer coupled between the glass layer and the substrate forming a hermetic seal about the laser, angled reflective surface, and patterned diffuser.

30. The laser projector of claim 26 wherein the laser is supported by a metalized layer of the substrate.

31. The laser projector of claim 30 wherein the laser is positioned to project light in a direction parallel to a substrate surface and toward, the angled reflective surface.

32. The laser projector of claim 26 wherein the angled reflective surface comprises an etched silicon groove in the substrate and a metalized reflective layer supported on the etched silicon groove.

33. The laser projector of claim 32 wherein the metalized reflective layer comprises gold or silver.

34. The laser projector of claim 26 wherein the patterned diffuser comprises a pattern of concave polymer structures having an approximately 100 μm center to center pitch.

35. The laser projector of claim 34 and further comprising a glass layer coupled to the substrate and wherein the patterned diffuser is molded on the glass layer.

36. A laser projector comprising:
a substrate having a groove with an angled reflective surface;
a laser supported by the substrate and positioned to direct laser light onto the angled reflective surface of the groove;
a diffuser supported above at least a portion of the angled reflective surface of the groove and positioned to receive reflected laser light and provide a projected pattern of light away from the substrate.

37. The laser projector of claim 36 wherein the diffuser is positioned substantially parallel to a top surface of the substrate such that the projected pattern of light is projected orthogonal to the top surface of the substrate.

38. The laser projector of claim 36 wherein the groove has a shorter angled surface opposite the angled reflective surface, the shorter angled surface rising from a bottom of the groove to a flat laser support surface of the substrate, the laser support surface rising to a height part way up the angled reflective surface, below a top of the substrate at top of the angled reflective surface.

39. The laser projector of claim 38 and further comprising:
a glass layer supported by the top of the substrate, wherein the diffuser is supported by the glass layer; and
a spacer positioned between the glass layer and the flat laser support surface of the substrate.

40. The laser projector of claim 39 and further comprising metal contacts supported by the flat laser support surface of the substrate and coupled to the laser to provide power to the laser.

41. A laser projector comprising:
a substrate having an angled reflective surface;
a laser supported by the substrate and positioned to direct laser light onto the angled reflective surface;
means to receive laser light reflected from the angled reflective surface and provide a projected pattern of light away from the substrate.

42. The laser projection of claim 41 wherein the substrate comprises a silicon substrate and wherein the angled reflective surface comprises a side of a v-groove formed at 45 degree angle from a top surface of the silicon substrate.

43. A method of forming a laser projector, the method comprising:
creating an angled surface in a substrate;
applying a reflective material to the angled surface;
molding a diffuser to a plate of glass; and
bonding the plate of glass with molded diffuser to the substrate.

44. The method of claim 43 wherein the molded diffuser is positioned above the angled surface of the substrate and further comprising attaching a laser to the substrate.

45. The method of claim 44 wherein the laser is attached to the substrate such that the laser projects a laser onto the reflective material applied to the angled surface.

46. The method of claim 44 and further comprising forming a metalized layer on the substrate to couple to the laser.

47. The method of claim 43 wherein creating an angled surface in a substrate comprises performing silicon-V etching to create an approximately 45° groove.

48. The method of claim 47 and further comprising:
forming a planar substrate surface lower than a top of the angled surface having the reflective material; and
attaching a laser to the lower planar substrate surface such that laser light projected from the laser impinges on the reflective surface and is reflected though the diffuser.
